(19) United States
(12) Patent Application Publication
(10) Pub. No.: US 2006/0185718 A1
(43) Pub. Date: Aug. 24, 2006

(54) High energy photon power source

(75) Inventors: Wayne E. Abare, Malabar, FL (US); Robert J. Williford, Melbourne, FL (US); Arecio A. Hernandez, Melbourne, FL (US)

Correspondence Address: GRAY ROBINSON, P.A., 401 E. LAS OLAS BLVD., SUITE 1850, FT. LAUDERDALE, FL, 33301, US

(73) Assignee: Harris Corporation

(21) Appl. No.: 11/063,346

(22) Filed: Feb. 23, 2005

(51) Int. Cl. H01L 31/00

(52) U.S. Cl. 136/253

(57) ABSTRACT

An energy cell, employed as a passive energy source, takes advantage of the differing electrical properties of metals to produce an induced electromagnetic force charge when exposed to dosages of high energy photons such as x-ray or gamma rays.

### FIELD OF THE INVENTION

This invention is directed to devices operative in response to impingement by high energy photons, and, more particularly, to a passive energy source which exploits the electrical characteristics of metals having different atomic numbers when exposed to a dosage of high energy photons such as x-rays or gamma rays.

### BACKGROUND OF THE INVENTION

One of the challenges for many electronics programs is how to reduce the size and weight of electronics components. In larger systems, such as aircraft and spacecraft, every savings in size and weight increases payload and mission capabilities. It is equally important in miniature systems, such as certain types of medical devices, where each reduction can open a range of applications previously inaccessible at larger scales.

One of the key constraints in any electronics system is the demand for some form of local energy to provide power for the system components. Typical solutions include one or more forms of fuel-based power generation, such as fossil or nuclear fuels, or an energy storage device, e.g. a battery. Other applications employ “passive” energy sources such as photovoltaic panels which are commonly used in spacecraft and other equipment in which the energy source cannot be readily replaced. Solar panels, for example, tend to require a substantial amount of surface area to create useful amounts of electrical energy, adding unwanted size and weight. Further, solar panels must be directed toward the sun to operate efficiently and it can be difficult to maintain the appropriate attitude of the panels to maximize exposure to the sun.

### SUMMARY OF THE INVENTION

This invention is directed to an energy cell employed as a passive energy source, which, when exposed to dosages of high energy photons such as x-rays or gamma rays, produces an induced electromagnetic force charge.

It has long been known that every metal ejects electrons from its surface in response to the impingement by photons of a sufficient energy level. The linear absorption coefficient of a particular metal is the sum of different phenomenon, including Thomson scattering, photoelectric absorption, Compton scattering, pair production and photodisintegration. Thomson scattering occurs when high energy photons, such as x-ray photons, scatter after impingement with the metal and there is no change in energy to either the atom of the metal or the x-ray photon. Photoelectric absorption occurs when the atom of a metal absorbs the x-ray photon, resulting in electrons being ejected from the outer shell of the atom and the ionization of the atom. Compton scattering occurs when an x-ray photon ejects an electron from the metal atom, and an x-ray of lower energy is scattered from the atom. At the energy levels of x-ray photons, pair production and photodisintegration have little or no effect on the linear absorption coefficient.

In the past, the ejection of electrons from the surface of metals as a result of impingement by x-ray photons or other high energy photons such as gamma rays, had adverse effects on electronic systems of all types. The ejected electrons can damage certain electrical components, interfere with the transmission and receipt of data and cause other problems. As a result, efforts were undertaken to shroud such metal surfaces from impingement by photons to protect electrical components, circuits, instrumentation and the like from damage.

This invention is predicated on the concept of using the phenomena described above to create a passive source of electrical energy which exhibits a long life and is inexpensive, highly reliable, and sensitive. It can operate in extreme environmental conditions, requires little or no maintenance and can be integrated in a wide variety of applications and structures. In the presently preferred embodiment, an energy cell is provided comprising at least one metal element having a high atomic number, at least one second metal element with a comparatively low atomic number and a section of dielectric material located between the first and second metal elements. Such “metal elements” may be plates, a wire and sheath or essentially any other configuration in which metal layers are separated by dielectric material.

In one example, the energy cell may include a plate formed of gold and another plate formed of aluminum separated by a composite layer. In response to dosage of the plates with x-rays, both the gold plate and aluminum plate eject electrons. But because the gold plate has a comparatively higher atomic number, more electrons are ejected from it than the aluminum plate. This creates an electrical potential across the plates such that when a load is connected to them electrical energy, e.g., an induced electromagnetic force (IEMF) charge, flows from the plates to the load. The energy cell of this invention can be scaled in the sense that the physical size of the metal elements can be altered, as desired, and more than one energy cell may be connected together in series or parallel to increase the overall amount of electrical energy produced depending upon the requirement of a particular application.

There are a myriad of applications with which the energy cell of this invention may be utilized, at both the macro and micro level. It may be applied at a macro level to the housing or chassis of an electronic device, or to the cables, connectors, cable harnesses etc. of same. At a micro level, the energy cell herein may be embedded in a printed wiring board, affixed as a device on a circuit board, laminated on the surface of chips, embedded within the chip circuitry as well as other options.

### BRIEF DESCRIPTION OF THE DRAWINGS

The structure, operation and advantages of the presently preferred embodiment of this invention will become further apparent upon consideration of the following description, taken in conjunction with the accompanying drawings, wherein:

FIG. 1 is a schematic cross sectional view of one embodiment of the energy cell of this invention shown connected to a load;

FIG. 2 is a view of an alternative embodiment of the energy cell herein;

FIG. 3 is a schematic, plan view of a circuit board employing multiple energy cells;

FIG. 4 is a cross sectional view of a stack of printed circuit boards in which energy cells of this invention are embedded at different layers.

### DETAILED DESCRIPTION OF THE INVENTION

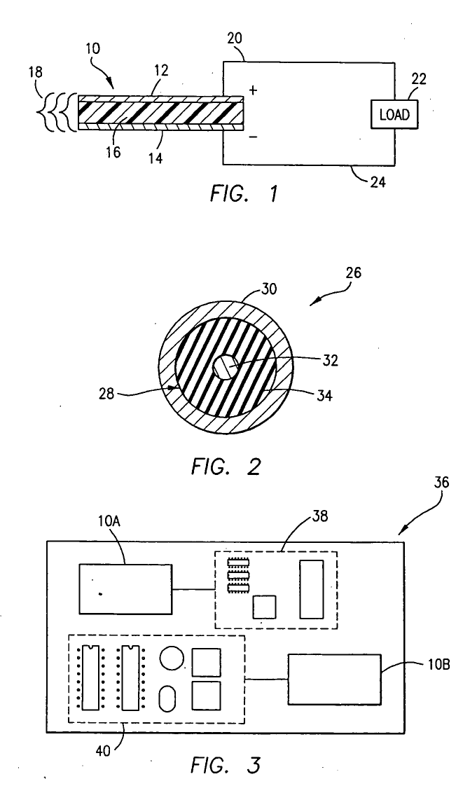

Referring now to FIG. 1, a schematic view of one embodiment of an energy cell 10 according to this invention is depicted. In this embodiment, the energy cell 10 comprises a first plate 12 and a second plate 14 separated by a layer 16 of dielectric material such as a composite material. The plate 12 is formed of a material having a relatively high atomic number, such as gold, whereas the plate 14 is formed of a material having a comparatively low atomic number such as aluminum. The energy cell 10 is subjected to a dose of high energy photons, such as x-rays or gamma rays, as schematically shown by the brackets 18 in FIG. 1.

As noted above, all metals eject electrons when impinged by photons of sufficient energy. Materials with higher atomic numbers eject a larger quantity of electrons than those with lower atomic numbers, assuming they are exposed to the same dosage of high energy photons, and therefore a potential difference is produced across the plates 12, 14 which is represented by a “−” sign associated with the gold plate 12 and a “+” sign associated with the aluminum plate 14. While both plates 12, 14 actually exhibit a negative charge, the charge on the gold plate 12 is more negative than that of the aluminum plate 14.

The gold plate 12 is shown connected by a lead 20 to a load 22, and the aluminum plate 14 is connected by lead 24 to the load 22. The term “load” as used herein is intended to broadly encompass a variety of circuits or devices which may be connected to the energy cell 10. In one aspect of this invention, the energy cell 10 is used as a passive energy source which provides electrical energy to essentially any number of different types of electrical circuits or devices which can be operated at voltage and current levels produced by the energy cell 10, as discussed below. Further, a suitable threshold circuit and driver circuit (not shown) may be interposed between the energy cell 10 and load 22 which collectively function to store electrical energy produced by the energy cell 10 and then discharge it to a circuit or device when it reaches a predetermined level. It should be noted that electrons are ejected by the plates 12, 14 only when they are impinged by the high energy photons, and in the absence of such photons the ejected electrons dissipate. As such, a storage device such as a conventional capacitor or threshold circuit may be employed to capture the electrical energy produced when the energy cell 10 is dosed with x-rays or other high energy photons.

FIG. 1 depicts one example of an energy cell according to this invention. It should be understood that other configurations of metal structures having different atomic numbers, separated by a dielectric material, can form an energy cell which is considered within the scope of this invention. For example, in FIG. 2 an energy cell 26 is shown which consists of an insulated wire 28 surrounded by a sheath 30. The insulated wire 28 has a core 32 of aluminum or a similar material with a relatively low atomic number surrounded by a rubber insulator 34, and the sheath 30 is preferably formed of gold or other material with a comparatively high atomic number. The energy cell 26 of this embodiment functions in the same manner as energy cell 10, and may be used in the same types of applications, as desired.

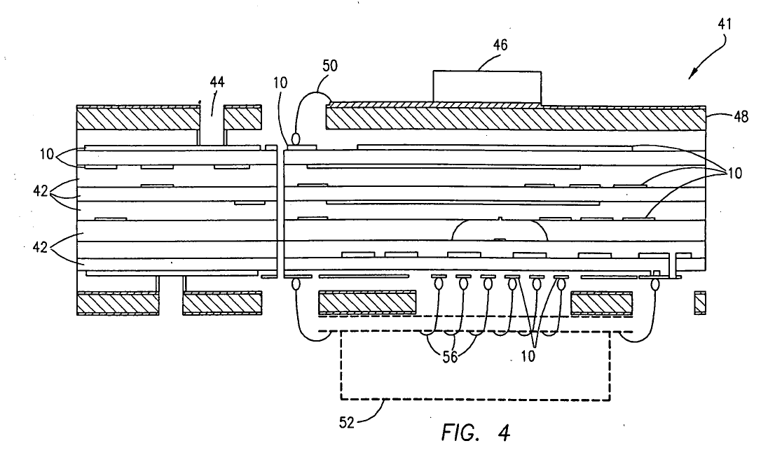

Referring now to FIGS. 3 and 4, the energy cell 10 is shown in two specific applications for purposes of illustration. In FIG. 3, two energy cells 10A and 10B, are mounted to the surface of a printed circuit board 36 having a variety of electrical components contained in discrete circuits 38 and 40. The circuit 38 is schematically shown as being connected to and powered by the energy cell 10A, whereas circuit 40 is powered by energy cell 10B.

In FIG. 4, a printed wiring board 41 is shown having a number of layers 42 stacked one on top of the other and multiple ground vias 44. A number of discrete energy cells 10 are embedded at selected locations throughout the thickness of the board 41 to provide power for various electrical components carried by the board 41. Lower energy x-ray bands charge the upper layers 42 of the stack, and higher energy x-ray bands penetrate to charge the lower layers 42. It is contemplated that the higher energy x-ray bands will be partially absorbed by the upper layers 42, which reduces their band energy and therefore increases the IEMF charge on the lower layers 42 of the stack. One circuit 46 is shown at the top layer 48 of the board 41 connected by a lead 50 to one or more energy cells 10. A number of independent circuits or individual electrical components (not shown) may be located within a housing 52 which is schematically depicted at the base of the board 41. A separate lead 56 may be extended between each of such components or circuits and discrete energy cells 10, as shown.

As noted above, factors such as the physical size of the plates 12, 14 (or wire 28 and sheath 30), the duration of their exposure to high energy photons and whether more than one energy cell 10 or 26 are connected together can affect the total electrical energy produced. In one example, a 1 mil thick gold plate having length and width dimensions of 1 inch by 1 inch, and a 1 mil thick aluminum plate with the same dimensions were placed on either side of a 1.5 mil thick section of fiberglass dielectric material and irradiated with x-rays. A 42 Rad (Si) dose of x-rays applied to this test sample for a period of 0.5 minutes resulted in a voltage of about 0.57 volts, a 168 Rad (Si) dose applied to such sample for a period of 2 minutes produced a voltage of about 0.8 volts, and, a 294 Rad (Si) dose applied to the sample for a period of about 3.5 minutes produced a voltage of about 1.18 volts. Testing and software simulations indicate that about 39% of the x-ray energy applied to the energy cell example noted above was “harvested” in the form of an IEMF charge. It is contemplated that levels of electrical energy suitable for a wide variety of applications can be produced by the energy cells 10 or 24 of this invention, when used either as a source of energy or a detector of the presence of high energy photon irradiation.

While the invention has been described with reference to a preferred embodiment, it should be understood by those skilled in the art that various changes may be made and equivalents substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. An energy cell, comprising:
a first element formed of a first material, said first element being effective to eject a quantity of electrons in response to impingement by high energy photons;
a second element spaced from said first element, said second element being formed of a second material which is effective to eject a lesser quantity of electrons, compared to said first element, in response to impingement by high energy photons, an electrical potential being created across said first and second elements;
a dielectric material located between said first and second elements.

2. The energy cell of claim 1 in which said first material is gold.

3. The energy cell of claim 1 in which said second material has a second atomic number which is lower than an atomic number of said first material.

4. The energy cell of claim 3 in which said second material is aluminum.

5. The energy cell of claim 1 in which said first element is a plate, and said second element is a plate.

6. The energy cell of claim 1 in which said second element is a wire, said dielectric material is an insulator wrapped about said wire and said first element is a layer of said first material covering said insulator.

7. The energy cell of claim 1 in which said first and second elements produce electrical energy when connected to a load.

8. A source of electrical energy, comprising:
a first element formed of a first material, said first element being effective to eject a quantity of electrons in response to impingement by high energy photons;
a second element spaced from said first element, said second element being formed of a second material which is effective to eject a lesser quantity of electrons, compared to said first element, in response to impingement by high energy photons;
a dielectric material located between said first and second elements; and
an electrical potential being created across said first and second elements as a result of the different quantities of electrons ejected by respective elements, said first and second elements, when connected to a load, producing electrical energy.

9. The source of electrical energy of claim 8 in which said first material is gold.

10. The source of electrical energy of claim 8 in which said second material has an atomic number lower than an atomic number of said first material.

11. The source of electrical energy of claim 10 in which said second material is aluminum.
